(19) United States
(12) Patent Application Publication
(10) Pub. No.: US 2025/0248013 A1
(43) Pub. Date: Jul. 31, 2025

(54) Apparatuses, systems, and methods for electromagnetic interference (EMI) suppression

(71) Applicant: Oleksandr Chernyashevskyy, White Plains, NY (US)

(72) Inventor: Oleksandr Chernyashevskyy, White Plains, NY (US)

(21) Appl. No.: 18/960,395

(22) Filed: Nov. 26, 2024

Related U.S. Application Data
(63) Continuation of application No. 63/603,190, filed on Nov. 28, 2023.

(51) Int. Cl. H05K 9/00

(52) U.S. Cl. CPC H05K 9/00

(57) ABSTRACT

The present invention provides an EMI suppression system comprising at least one of: (a) a source of one or more preselected forms of energy having one or more energy output ports that are coupled to an energy conversion subsystem, and (b) an energy conversion subsystem having one or more energy input ports and one or more energy output ports configured to convert the preselected forms of energy coming from the source of energy to one or more predefined forms of energy; wherein at least one energy conversion subsystem output port configured to provide the energy to at least one load. A form, a shape, a format, dimensions, and materials of the sources of energy and energy conversion subsystems are selected and configured for suppression of EMI energy from EMI sources of natural and artificial origin to one or more loads and vice versa.

### CROSS REFERENCE TO RELATED APPLICATION

The present invention claims the benefit under 35 U.S.C. § 119(e) of U.S. Provisional Application Ser. No. 63/603,190 filed Nov. 28, 2023, entitled “Scalable EMI/RFI suppression system and method”, which is incorporated herein by reference in its entirety. SEP

### TECHNICAL FIELD

The present disclosure generally pertains Electromagnetic Interference (EMI) and/or Radio Frequency Interference (RFI) suppression systems, apparatuses and methods. More particularly, the invention concerns systems and apparatuses for EMI/RFI suppression to a predetermined level emanation of EMI energy caused by sources of natural and artificial origin to a load and vice versa and method for forming the same.

### SUMMARY OF THE INVENTION

In one aspect, the present invention provides an electromagnetic interference (EMI) energy suppression system comprising at least one of:
(a) a source of one or more preselected forms of energy having one or more energy output ports; and
(b) an energy conversion subsystem having one or more energy input and one or more energy output ports.

The energy conversion subsystem is configured to convert energy coming from the source of energy to one or more predefined forms of energy; wherein
at least one energy conversion subsystem output port is configured to provide one or more forms of energy to at least one load; wherein
a form, a shape, a format, a dimension, and materials of the source of energy and energy conversion subsystem are selected and configured to suppress to a predetermined value a propagation of EMI energy from the sources of EMI energy of natural and artificial origin to the load and vice versa.

In another aspect, the present invention provides a method for an EMI suppression, the method comprising steps of:
providing one or more sources of one or more predefined forms of energy having one or more energy output ports;
forming an energy-carrying communication subsystem for one or more forms of energy having one or more input and output ports;
configuring an energy conversion subsystem having one or more energy input and output ports for conversion energy coming from the source of energy to one or more predetermined forms of energy;
operatively coupling the energy-carrying communication subsystem input port with the source of energy output port;
operatively coupling the energy-carrying communication subsystem output port with the input port of the energy conversion subsystem;
configuring at least one port of energy conversion subsystem for providing one or more forms of energy to one or more loads;
configuring a form, a shape, a format, a dimensions, and a materials of the source of energy, energy-carrying communication system and energy conversion system to suppress to a predetermined value a propagation of EMI energy from the sources of EMI energy of natural and artificial origin to one or more loads and vice versa.

In yet another aspect, the present invention provides an EMI energy suppression system for suppressing an EMI energy passage from a sources of EMI energy of natural and artificial origin to a load and vice versa, comprising at least one of:
(a) a source of thermal energy having one or more energy output ports;
(b) a subsystem for conversion of thermal energy to electric energy having one or more thermal energy input ports and one or more electric energy output ports, and
(c) a heat sink; wherein
at least one thermal energy output port of the source of thermal energy is operatively coupled to at least one energy input port of the energy conversion subsystem; wherein
at least one thermal energy output port of the energy conversion subsystem is operatively coupled to at least one heat sink; wherein
at least one electric energy output port of the energy conversion subsystem is configured to provide electric energy to one or more loads; wherein
a form, a shape, a format, a dimensions, and a materials of the source of thermal energy and the thermal to electric energy conversion subsystem are selected and configured for suppression to a predetermined value the passage of the EMI energy from the sources of EMI energy of natural and artificial origin to one or more loads and vice versa.

The drawings do not illustrate all possible embodiments of the present disclosure. The sizes and relative positions of elements in the drawings are not necessarily drawn to scale. Further, the particular shapes of the parts and elements as drawn are not intended to convey any information regarding the actual shape of the particular elements because present specification may be practiced without such details. Furthermore, schematic illustrations may not reflect fabrication technique limitations which may cause the real structures, parts, subsystems, systems and elements to look not so perfect.

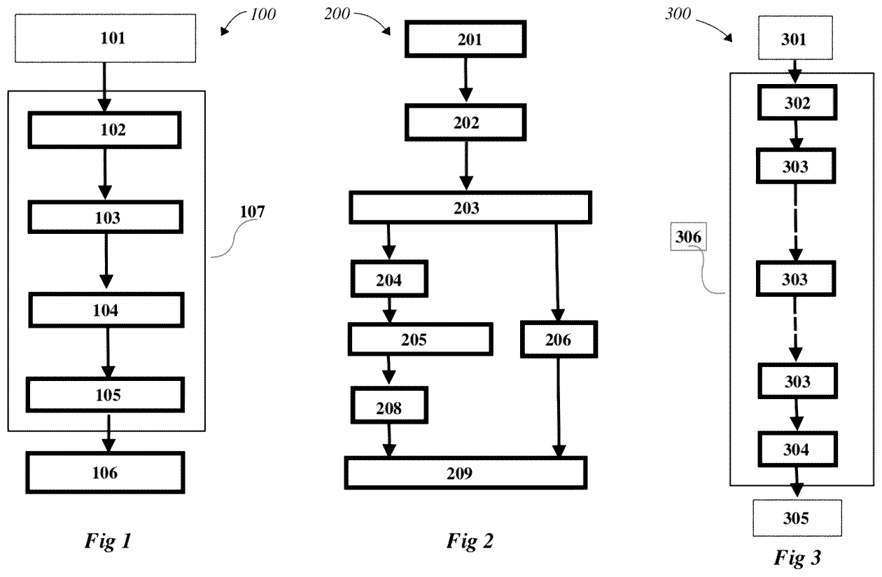

FIG. 1 is a generalized conceptual diagram of an embodiment of an EMI suppression system powered by a chemical reactor.

FIG. 2 is a generalized conceptual diagram of an embodiment of an EMI suppression system having two energy conversion subsystem.

FIG. 3 is a generalized conceptual diagram of an embodiment of an EMI suppression system having a cascade of energy conversion subsystem.

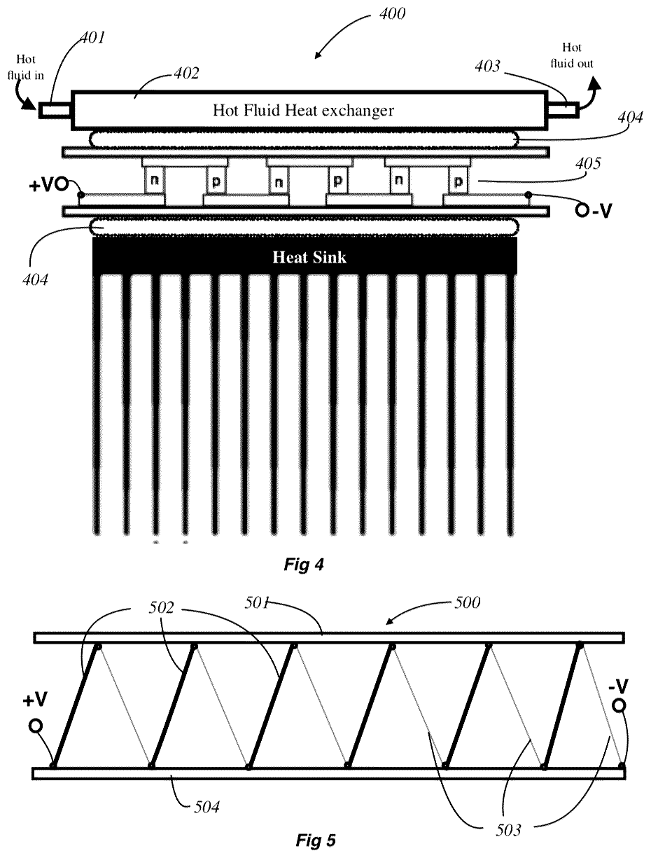

FIG. 4 is a simplified cross sectional side view an embodiment of an EMI suppression system having TEG energy conversion subsystem.

FIG. 5 is a simplified sectional side view of thermopile energy conversion subsystem.

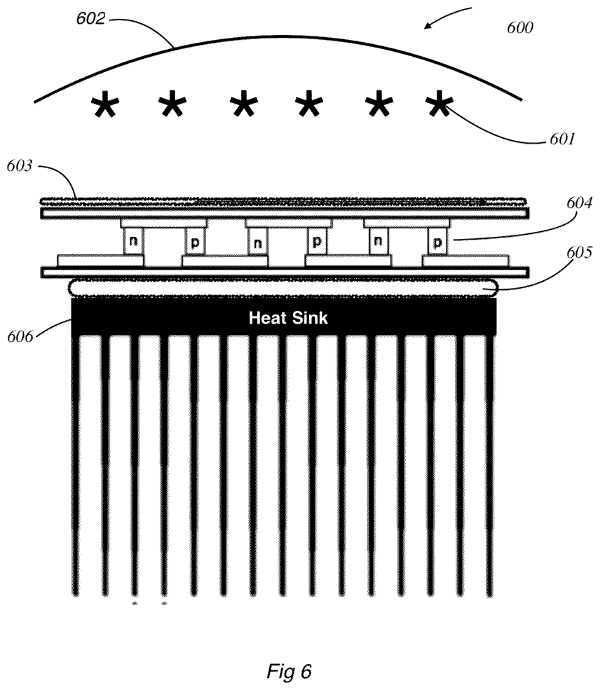

FIG. 6 is a simplified sectional side view of an embodiment of an EMI suppression system having two energy conversion subsystem.

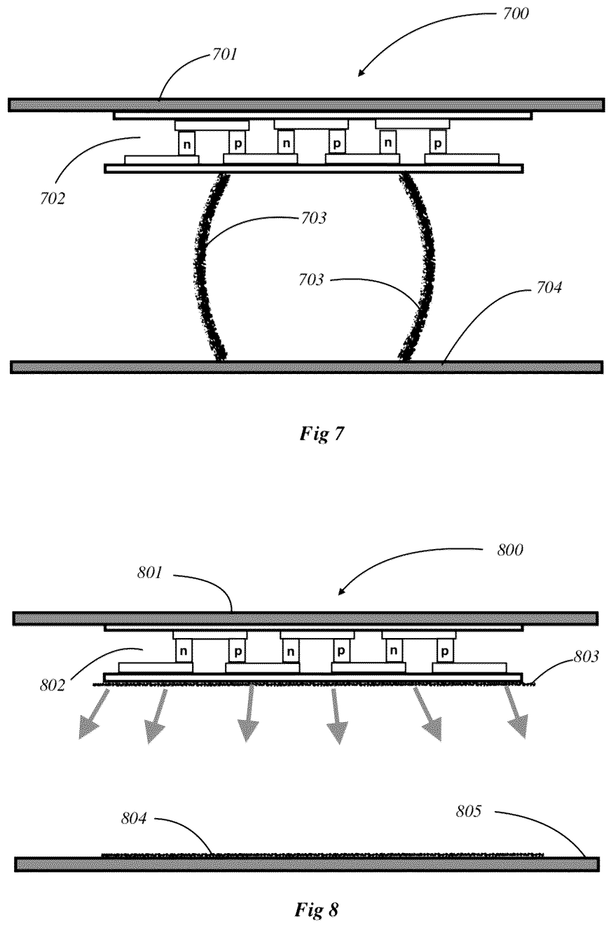

FIGS. 7, 8 are a simplified sectional side view of an embodiment of an EMI suppression system having thermal energy conversion subsystem.

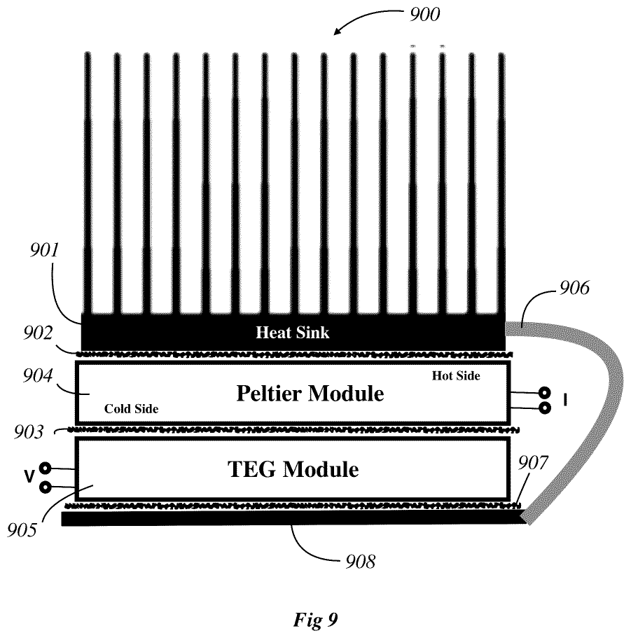

FIG. 9 is a simplified cross sectional side view of an embodiment of an EMI suppression apparatus.

### DETAILED DESCRIPTION OF THE INVENTION

Present disclosure includes a variety of aspects, which may be combined in different ways. Throughout this specification an embodiments of the disclosure herein may be configured as an apparatus, system, method, or any combination of these. However it should be understood that select embodiments may be combined in any manner and in any number to create additional embodiments. This invention is assumed to include many physical installation options. Furthermore, the claimed subject matter is not limited to implementations that solve any or all disadvantages noted in any part of this invention.

It should be noted that combination of present invention subject matter with known in the art EMI shielding, absorbing and/or filtering may further improve overall EMI suppression. A discussion of elements, structures and steps well known in the art like EM shielding, EM absorbing and EMI filtering are not provided herein, because they do not facilitate a better understanding of the present invention.

As used herein, the term “electromagnetic interference” interchangeably refers hereinafter to electromagnetic interference (EMI), and radio-frequency interference (RFI), derived from any source of natural or artificial origin including electromagnetic radiation, electromagnetic induction, magnetism, electrostatic fields, conducted EMI and like and any combination of these.

As used herein, the term “form of energy” refers hereinafter to form of energy selected from a group consisting of chemical energy, thermal energy, electrical energy, radiant energy, sound energy, motion energy, mechanical energy, nuclear energy, gravitational energy and the like, whether now known or later developed, or a combination of these.

As used herein, the term “energy conversion” refers hereinafter to the process of changing one form of energy to another.

As used herein, the term “load” refers hereinafter to an electronic element, apparatus or system that consumes one or more forms of energy selected from group consisting of chemical energy, thermal energy, electrical energy, radiant energy, sound energy, motion energy, mechanical energy, nuclear energy, gravitational energy, and the like, whether now known or later developed, or a combination of these.

As used herein, the term “energy conversion subsystem” interchangeably refers hereinafter to “energy transformation system,” i.e., to a system, subsystem, or apparatus designed to operatively change one form of energy into another form of energy.

As used herein, the term “energy-carrying communication subsystem” refers to apparatus and/or system/subsystem configured for giving, receiving, exchanging, operatively relocating one or more forms of energy from one element, apparatus and/or system to another element, apparatus and/or system.

As used herein, the term “operatively coupling” refers hereinafter to connection of

multiple systems, subsystems, elements, and/or ports in such a manner that various forms of energy, voltage, current, or various signals are passing from one subsystem, element, and/or port to another subsystem, element, and/or port and vice versa.

As used herein, the term “electromagnetic shielding” refers to a technique of suppressing an electromagnetic field coming from natural and/or artificial sources. EM shielding of at least a portion of system, subsystem, and/or element may further improve EMI energy suppression. For instance inductive, conductive, radiated and capacitive coupling between the natural and/or artificial sources of EMI energy and a load may be at least partially suppressed by carefully selected and configured electromagnetic shielding.

As used herein, the term “exo-energetic mode” refers to operation of a chemical reactor, system, subsystem, and/or element, whether now known or later developed, that releases one or more forms of energy.

As used herein, the term “endo-energetic mode” refers to operation of a chemical reactor, system, subsystem, and/or element, whether now known or later developed, that operatively absorbs one or more forms of energy.

In various embodiments, without harm to scalability or scaling down an energy conversion and an energy-carrying communication subsystem may be configured for at least partial reduction of an EMI energy passage from the sources of energy and surrounding environment to the load and vice versa.

In some embodiments the passage of EMI energy through the energy conversion and the energy-carrying communication subsystem may be suppressed without harm to energy conversion efficiency and/or performance.

In another embodiment the energy conversion subsystem of the EMI energy suppression system may include a chemical reactor. The chemical reactor may be configured to operate in exo-energetic and/or endo-energetic mode by selecting a chemical reactant and/or reactor design.

In various embodiment, one or more subsystems of EMI suppression system may be at least partially barricaded by one or more EM shields, shaped pieces of EM absorption material, or any combination thereof.

In still another embodiment, the one or more components can be integrated into one or more subsystems of EMI suppression system.

In some embodiment, the EM shield can be operatively coupled to a reference potential point or a signal line that is shared with the electric energy output.

In another embodiment, the EM shield can be galvanically isolated from EMI suppression subsystem and sources of energy.

In some embodiments, the one or more EM shields can be operatively coupled to ground.

In another embodiments, the one or more EM shields can be operatively coupled to a reference potential.

In multiple embodiments one or more preselected electronic elements may be integrated into a subsystem selected from group comprising source of energy, energy conversion subsystem, energy-carrying communication subsystem, or a combination of these. One of ordinary skill in the art will appreciate that EMI filters assembled from the implemented elements can be employed in the practice of the invention without resort to undue experimentation and further improve the overall EMI suppression.

In various embodiments an environment friendly transient materials, parts, electronic elements, or any combination of these may be integrated into EMI suppression system. For instance, EMI suppression system may include combination of degradable high performance single crystalline inorganic materials with degradable substrates.

### SELECT EXAMPLES

Example 1 provides scalable EMI suppression system having at least one energy conversion subsystem wherein an output energy suit the needs of a particular application. The EMI suppression system may operate without harm to energy conversion efficiency and/or performance.

Example 2 may include the subject matter of Example 1, and may further specify source of energy 201 (FIG. 2), first energy conversion subsystem 203 and second energy conversion subsystem 205 configured to provide two forms of energy to load 209 wherein 202, 204, 206 and 208 are energy-carrying subsystem.

Example 3 provides scalable EMI suppression system having one or more chemical reactors 102 (FIG. 1) configured to generate one or more forms of energy having one or more energy output ports, a subsystem for streaming of one or more reactants 101 for introduction into the reactor and exhaust subsystem for a reactor product/waste material and/or heat removal elements (not shown) wherein the reactor energy output ports are operatively coupled with the energy-carrying communication subsystem 105 having one or more electric energy output ports. The chemical reactor, reactant and product streaming system are selected by principle of operation and configured by the form, shape, dimensions and materials to suppress to predetermined value propagation of EMI energy from surrounding environment including but not limited to industrial environment, to load and vice versa.

Example 4 may include the subject matter of Example 2 and/or Example 3, and may further specify an EM shield 107, 306 at least partially disposed over one or more EMI sensitive components.

Example 5 may include the subject matter of Example 1 and/or Example 2, and may further specify a cascade of EMI suppression system wherein energy conversion system of multiple form of energy configured for energy-carrying communication in series. For example, the first suppression system provide energy to a pre-amplifier and second suppression system. Consequently the second suppression system provide energy to third suppression system and a sensor excitation circuitry. Then third suppression system provide bias to the sensor.

Example 6 may include the subject matter of Example 1,2 and/or 4, and may further specify one or more energy conversion subsystems adapted and configured for conversion of one or more forms of energy to an electric energy.

Example 7 provides the EMI suppression system having plural source of energy of multiple form in energy and/or data signal-carrying communication with plural energy conversion subsystem selected to suit the needs of a particular application.

Example 8 may include the subject matter of Example 7, and may further specify EMI/RFI suppression system further providing a data-carrying communication to/from the load via the same path with energy-carrying communication.

Example 9 may include the subject matter of Example 1, and may further specify a multiple energy conversion subsystem 200. For example the 1st energy conversion subsystem 203 convert a first form of energy coming from source 201, for instance radiant energy, to a 2nd form of energy, for instance, thermal energy, the 2nd energy conversion apparatus 205 in energy-carrying communication 202, 204, 208 convert the second form of energy to an electric energy.

Example 10 may include the subject matter of Example 1-7, and may further specify the energy conversion subsystem disposed essentially close to a Points of Load of an EMI vulnerable circuitry, apparatus or system.

Example 11 provides scalable EMI suppression system integrated and configured to operate with cooling/heating apparatus/system, for example a cryostat 700, 800. A thermoelectric generator (TEG) 702, 802 and/or thermopile 502, 503 may be adapted with the help of 701, 704, 801, 803, 804, 805 and configured for conversion of heat energy to electrical energy.

Example 12 may include the subject matter of Example 3, and may further specify EMI suppression system wherein chemical reactor is designed and configured in form of a fuel cell.

Example 13 provides scalable EMI/RFI suppression system wherein at least a portion of energy-carrying communication configured to operate with shaped pieces of various EMI/RFI absorbing material. For example, composite thermal conducting pads 404, 603, 605, 903, 905 and 907 may include radiant energy-absorbing particles.

Example 14 may include the subject matter of Example 2 and/or Example 13, and may further specify a thin film of radiant energy-absorbing material at least partially disposed over one or more sources of energy and/or at least one subsystem of EMI suppressing system.

Example 15 may include the subject matter of Example 1-3, and may further specify EMI/RFI suppression apparatus 400 (FIG. 4). A hot or cold fluid or gas streams thermal energy from a source of energy (not shown) to heat exchanger 402. An EMI energy absorption thermal conducting pads 404 are streaming thermal energy to a TEG module 405 and from the TEG module to heat sink. The TEG module converts thermal energy, and at least partly EMI energy to electric energy.

Example 16 may include the subject matter of Example 1-3, and may further specify EMI/RFI suppression system 600 (FIG. 6). An electric energy (not shown) and at least partly EMI energy converts to a radiant energy in converter 601. An EMI energy absorption thermal conducting pad 603 absorbs radiant and at least part of EMI energy to thermal energy and stream it to a TEG module 604 and from the TEG module to heat sink. The TEG module converts thermal energy and at least partly EMI energy to electric energy.

Example 17 may include the subject matter of Example 1-5, and may further specify yet another EMI suppression system 700 (FIG. 7). A TEG 702 disposed on “hot” part/wall 701 (of a system) and is in energy-carrying communication 703 with “cold” 704 part/wall of a system. The TEG 702 converts thermal energy flow from hot 701 to cold 704 part to electric energy. The system walls may be configured for/to at least partial EM shielding for TEG 702.

Example 18 may include the subject matter of Example 1-7, and may further specify yet another EMI/RFI suppression system 800 (FIG. 8). A TEG 802 disposed on “hot” part/wall 801 and is in energy-carrying communication with “cold” 805 part/wall of a system by emitting infra-red (IR) radiation toward “cold” part/wall. The TEG 802 converts thermal energy flow to electric energy. A coating for improving IR emission 803 and absorption 804 may be disposed over “hot” IR emitting and “cold” IR absorbing surface for improve thermal energy flow and overall efficiency. The system walls may be configured as at least partial EM shielding for EMI attenuation around energy converter 802.

Example 19 may include the subject matter of Example 17 and/or 18, and may further specify EMI/RFI suppression apparatus 900 (FIG. 9). A Peltier module 904 convert electric energy and at least partly EMI energy to a thermal energy. The EMI energy absorption thermal conducting elements 902, 903, 906, and 907 are absorbing at least partially the EMI energy and streaming thermal energy to a TEG module 905, and from the TEG module to heat sink 901. The TEG module converts thermal energy and at least partly EMI energy to electric energy.

Example 20 may include the subject matter of Example 19, and may further specify unwanted EMI energy-absorbing/trapping elements. For example, disposing of shits of radiant energy-absorbing material over at least a portion of one or more sources of energy, and/or subsystems of EMI suppression system may further improve overall EMI suppression.

Example 21 provides scalable EMI suppression apparatus, and may further specify triboelectric generator configured for harvesting mechanical energy and converting it to electric energy.

The examples and preferred embodiments in this specification should not be construed to limit the present invention to only the explicitly just described systems, apparatuses and applications. Those skilled in the relevant art will recognize a methods and techniques for forming a scalable EMI suppression system element described above as the systems, apparatuses and applications.

The aspects of the present systems, methods and apparatuses can be modified, if necessary, to employ systems, methods, techniques, apparatuses and concepts of the various patents, applications and publications to provide yet further embodiments of the present methods and systems. Further, the invention according to current specification is applicable to other embodiments or of being practiced or carried out in various ways. For example, an applications with any number of the disclosed elements, with each element alone, and also with any and all various permutations, and combinations of all elements in this, or any subsequent application. Furthermore, those of skill in the art will appreciate that, the actions recited in the claims can be performed in a different order and still achieve desirable results.

It is to be appreciated that the concepts, systems, circuits and techniques of current disclosure are not limited to use in a particular application. In contrast, the concepts, systems, circuits and techniques may be found useful in substantially any application where a manufacturer desires to integrate EMI energy suppression apparatus, system and/or method.

### PATENT CITATIONS (5)

Robert Simpson, THERMOGAS DYNAMICS Ltd. Methods and systems for energy conversion and generation. U.S. Pat. No. 10,208,665B2, 2019 Feb. 19.
Joerg U. Fechau, Kenneth A. Kotyuk, Randall J. Dias, Tandem ComputersInc. Electronic assembly with improved grounding and emissions shielding. Canada CA2114325C, 1997 Jan. 28.
Matthew Kelley, Christian Adams, Patric A. Nelson, Lockheed Martin Corp. Serviceable conformal em shield. U.S. Pat. No. 8,716,606B2, 2014 May 6.
John A. Rogers, Hian Huang, University of Illinois. Biodegradable materials for multilayer transient printed circuit boards. U.S. Pat. No. 10,292,263B2, 2016 Feb. 18.

### NON PATENT CITATIONS (1)

Keith Armstrong, Design Techniques for EMC Part 4—Shielding (screening) Originally published in the EMC Compliance Journal in 2006-9, and available from http://www.compliance-club.com/KeithArmstrong.aspx

What is claimed is:

1. A scalable EMI energy suppression system for suppressing an EMI energy passage from EMI sources of natural and artificial origin to one or more loads and vice versa, the system comprising:
at least one source of one or more preselected forms of energy having one or more energy output ports; and
at least one energy conversion subsystem having one or more energy input ports and one or more energy output ports; wherein
at least one source of energy output port is operatively coupled to at least one energy input port of the energy conversion subsystem; wherein
every energy conversion subsystem is configured to convert one or more preselected forms of energy to one or more predefined forms of energy; wherein at least one energy output port of the energy conversion subsystem configured to provide one or more forms of energy to the one or more loads; wherein
a form, a shape, a format, a dimensions, and a materials of the source of energy and the energy conversion subsystem are selected and configured for suppressing to a predetermined value the passage of the EMI energy from the one or more sources of energy and the surrounding environment to the load and vice versa.

2. A scalable EMI energy suppression system for suppressing an EMI energy passage from EMI sources of natural and artificial origin to one or more loads and vice versa, comprising:
at least one source of thermal energy having one or more energy output ports, and at least one heat sink; and
at least one thermal energy to electric energy conversion subsystem having one or more thermal energy input ports, one or more thermal energy output ports, and one or more electric energy output ports; wherein
at least one thermal energy output port of source of energy is operatively coupled to at least one energy input port of the energy conversion subsystem; wherein at least one energy conversion subsystem thermal energy output port is operatively coupled to at least one heat sink; wherein
at least one electric energy output port of the energy conversion subsystem is configured to provide electric energy to one or more loads; wherein
a form, a shape, a format, a dimensions, and a materials of the source of thermal energy, the thermal to electric energy conversion subsystem, and the heatsink are selected and configured for suppressing to a predetermined value the passage of the EMI energy from the one or more sources of energy and the surrounding environment to the load and vice versa.

3. The scalable EMI suppression system according to claim 1 or 2, further comprising one or more energy-carrying communication subsystems for one or more forms of energy having one or more energy input ports and one or more energy output ports configured to propagate the energy from the one or more sources of energy output ports to the one or more energy conversion input ports;
wherein
the one or more sources of energy output ports are operatively coupled to the one or more one energy-carrying communication subsystem energy input ports; and
one or more one energy-carrying communication subsystem energy output ports are operatively coupled to one or more energy conversion subsystem energy input ports; wherein
a form, a shape, a format, a dimensions and a materials of the energy-carrying communication subsystem are selected and configured for suppressing to the predetermined value the passage of EMI energy from the sources of energy and surrounding environment to the energy conversion subsystem and vice versa.

4. The scalable EMI suppression system according to claim 1 or 2, further comprising a cascade of a plurality having predetermined number N of energy conversion, and a plurality having predetermined number M of energy-carrying communication subsystem;
wherein
one or more first energy conversion subsystems are operatively coupled to the source of energy via the first energy-carrying communication subsystem; wherein
the energy output port of every energy conversion subsystem is operatively coupled directly or via the energy-carrying communication subsystem to the next in succession energy conversion subsystem energy input port; wherein
a predetermined number of at least one output port of the energy conversion subsystem configured to provide one or more forms of energy to the load; wherein the number and an operative coupling sequence of the cascade of the energy conversion subsystem are selected and configured for suppressing EMI energy passage to the predetermined value from the sources of energy and surrounding environment to the load and vice versa.

5. The scalable EMI suppression system according to claim 1 or 2, wherein the source of energy is one or more chemical reactors configured to generate one or more forms of energy having one or more energy output ports; and a subsystem for flowing multiple predefined reactants for introduction into the chemical reactor; and a subsystem for flowing the chemical reactor product outside the reactor;
wherein at least one energy output port of the chemical reactor is operatively coupled to one or more loads;
wherein a form, a shape, a format, a dimensions and a materials of the chemical reactor, reactant, product, and reactant and the product flowing subsystems are selected and configured for suppressing to a predetermined value the passage of EMI energy from surrounding environment to the load and vice versa.

6. The scalable EMI suppression system according to claim 1 or 2, wherein one or more sources of energy selected, formed, and configured for harvesting an energy of one or more forms from a surrounding environment; wherein
one or more sources of energy further configured for providing captured energy to the one or more source of energy output ports.

7. The scalable EMI suppression system according to claim 1 or 2, further comprising one or more preselected electronic elements integrated into a subsystem selected from group comprising source of energy, energy conversion subsystem, energy-carrying communication subsystem, or combination of these;
wherein.
the electronic elements are operatively coupled and configured for suppressing to the predetermined value EMI energy passage from the sources of energy and surrounding environment to the load and vice versa; wherein
at least one of the following is being held true:
(a) one or more electronic elements are galvanically coupled to the ground or reference potential of a utility distribution mains or load;
(b) one or more electronic elements are electrically isolated from the ground or reference potential of the load or a utility distribution mains.

8. The scalable EMI suppression system according to claim 1 or 2, further comprising one or more electromagnetic (EM) shields; wherein
the EM shields are disposed over at least a portion of one or more subsystems selected from a group consisting of the source of energy, the energy conversion subsystem, or a combination thereof; wherein
a form, a shape, a format, a dimensions and a materials of the EM shields are selected and configured for suppressing EMI energy passage to the predetermined value from the sources of energy and surrounding environment to the load and vice versa; wherein
at least one of the following is being held true
(a) one or more EM shields are galvanically coupled to the ground or reference potential of a utility distribution mains or load;
(b) one or more EM shields are electrically isolated from the ground or reference potential of the load or the utility distribution mains.

9. The scalable EMI suppression system according to claim 1 or 2, further comprising one or more shaped pieces of preselected EMI energy-absorbing material; wherein
the shaped pieces of the EMI energy-absorbing material are integrated into or disposed over at least a portions of one or more subsystems selected from a group consisting the source of energy, the energy conversion subsystem, and the energy-carrying communication subsystem, or a combination thereof; wherein
a form, a shape, a format, a dimensions and a materials of the shaped pieces of EMI energy-absorbing material are selected and configured for suppressing EMI energy passage to the predetermined value from the sources of energy and surrounding environment to the load and vice versa.

10. A method for forming a scalable EMI energy suppression system for suppressing an EMI energy passage from EMI sources of natural and artificial origin to one or more loads and vice versa, the method comprising of steps of:
providing one or more sources of one or more predefined forms of energy having one or more energy output ports;
providing one or more energy conversion subsystems having one or more energy input ports and one or more energy output ports;
operatively coupling one or more source of energy output ports with one or more energy conversion subsystem energy input ports;
configuring one or more energy conversion subsystems for conversion of one or more preselected forms of energy to one or more predefined forms of energy;
configuring the energy conversion subsystem one or more output ports for providing one or more forms of energy to one or more loads;
selecting and configuring a form, a shape, a format, a dimension, and a materials of the source of energy and energy conversion subsystem for suppressing EMI energy passage to a predetermined value from the sources of energy and the surrounding environment to the load and vice versa.

11. A method for forming a scalable EMI suppression system for suppressing an EMI energy passage from EMI sources of natural and artificial origin to one or more loads and vice versa, the method comprising steps of:
providing one or more sources of thermal energy having one or more thermal energy output ports;
providing one or more thermal energy to electric energy conversion subsystems having one or more thermal energy input ports, at least one heat sink and at least one electric energy output port;
operatively coupling the source of thermal energy output port with the thermal to electric energy conversion subsystem energy input port;
operatively coupling the thermal energy conversion subsystem one or more thermal energy output ports to at least one heat sink;
configuring the energy conversion subsystem electric output ports for providing the electric energy to one or more loads;
selecting and configuring a form, a shape, a format, a dimension and a materials of the source of thermal energy and the thermal to electric energy conversion subsystem for suppressing EMI energy passage to a predetermined value from the sources of energy and the surrounding environment to the load and vice versa.

12. The method for forming the EMI suppression system according to claim 10 or/11, further comprising steps of:
providing one or more energy-carrying communication subsystems for one or more predefined forms of energy having one or more energy input ports and one or more energy output ports
operatively coupling at least one source of energy output port to at least one energy-carrying communication subsystem energy input port;
operatively coupling at least one energy-carrying communication subsystem energy output port to the one or more energy conversion subsystem energy input ports;
selecting and configuring a form, a shape, a format, a dimension and materials of the energy-carrying communication subsystem for suppression to a predetermined value a passage of the EMI energy from sources of energy and the surrounding environment to the load and vice versa.

13. The method for forming the scalable EMI suppression system according to claim 10 or 11, further comprising steps of:
providing a plurality having number N of the energy conversion subsystems;
wherein N is an integer greater than 1;
providing a plurality having number M of the energy-carrying communication subsystems, wherein M is an integer greater than 1;
forming clusters of at least one energy-carrying communication subsystem and at least one energy conversion subsystem;
operatively coupling at least one energy output port of the energy-carrying communication system to one or more input ports of the energy conversion subsystem;
forming a cascade of the clusters of the energy conversion subsystem and energy-carrying communication subsystem; wherein
first in succession cluster is operatively coupled to source of energy; wherein
at least one cluster energy output port is operatively coupled to the input port of next in succession cluster;
operatively coupling a first energy conversion subsystem input port to the source of energy output port;
configuring a predetermined number of output ports of the energy conversion subsystem to provide one or more forms of energy to at least one load;
selecting the numbers M and N and configuring an operative coupling sequence of the subsystem of the cascade for suppressing EMI energy passage to a predetermined value from the sources of energy and the surrounding environment to the load and vice versa.

14. The method for forming the scalable EMI suppression system according to. claim 10 or 11, further comprising steps of:
providing one or more chemical reactors having one or more energy output ports;
providing a subsystem for moving one or more predefined reactants for introduction into the reactor and a subsystem for moving one or more chemical reactor product materials outside the reactor;
configuring the chemical reactor for generation or absorption of one or more predefined forms of energy;
operatively coupling at least one energy output port of the chemical reactor to at least one load;
selecting chemical reactor type, the types of subsystem for moving reactants into reactor, and the subsystem for moving reactor product outside the reactor for suppression of the passage of EMI energy from the surrounding environment to the load and vice versa;
configuring a form, a shape, a format, a dimensions, and a materials of the chemical reactor, the reactant, and the product moving subsystems for suppression to predetermined value the propagation of EMI energy from the surrounding environment to the load and vice versa.

15. The method for forming the scalable EMI suppression system according to claim 10 or 11, further comprising step of configuring the one or more sources of energy for harvesting one or more forms of energy from equipment and surrounding environment, and streaming the captured energy to the output ports of the source of energy.

16. The method for forming the scalable EMI suppression system according to claim 10 or 11, further comprising steps of:
providing at least one preselected electronic element;
integrating the preselected electronic element to one or more items selected from a group consisting of the source of energy, energy conversion subsystem, energy-carrying communication subsystem, or a combination thereof;
operatively coupling and configuring one or more electronic elements for suppression to a predetermined value of EMI energy passage from the sources of energy and the surrounding environment to the load and vice versa; wherein at least one of the following is being held true:
(a) one or more electronic elements are galvanically coupled to the ground or reference potential of a utility distribution mains or the load;
(b) one or more electronic elements are electrically isolated from the ground or reference potential of the load or a utility distribution mains.

17. The method for forming the scalable EMI suppression system according to claim 10 or 11, further comprising steps of:
providing one or more electromagnetic (EM) shields;
disposing of the EM shields over at least a portions of an item selected from a group consisting of the source of energy, the energy conversion subsystem, the energy-carrying communication subsystem, or a combination thereof;
selecting and configuring form, shape, format, dimensions, and materials of the EM shield for suppressing EMI energy propagation to a predetermined value from the sources of energy and surrounding environment to the load and vice versa;
wherein
at least one of the following is being held true
(a) one or more EM shields are galvanically coupled to the ground or reference potential of a utility distribution mains or the load;
(b) one or more EM shields are electrically isolated from the ground or reference potential of the load or the utility distribution mains.

18. The method for forming the scalable EMI suppression system according to claim 10 or 11, further comprising steps of:
providing shaped pieces of preselected EMI energy-absorbing material;
disposing of shaped pieces of preselected EMI energy-absorbing material over at least a portion of an item selected from a group consisting of the source of energy, the energy conversion subsystem, the energy-carrying communication subsystem, or a combination thereof;
selecting and configuring form, shape, format, dimensions and materials of the shaped pieces of EMI energy-absorbing material for suppressing EMI energy propagation to a predetermined value from the sources of energy and surrounding environment to the load and vice versa.
